(19) United States
(12) Patent Application Publication
(10) Pub. No.: US 2005/0091561 A1
(43) Pub. Date: Apr. 28, 2005

(54) Scan test method, device, and system

(76) Inventor: Hoi-Jin Lee, Sungnam-si (KR)

Correspondence Address: HARNESS, DICKEY & PIERCE, P.L.C., P.O. BOX 8910, RESTON, VA, 20195, US

(21) Appl. No.: 10/947,209

(22) Filed: Sep. 23, 2004

(30) Foreign Application Priority Data
Oct. 24, 2003 (KR) 2003-74686

(51) Int. Cl. G11C 29/00; G01R 31/28

(52) U.S. Cl. 714/718; 714/726

(57) ABSTRACT

A scan test method, device, and system may be provided to detect faults in embedded memories. The device may include a first select unit which may selectively output data inputs and may detect the faults in the embedded memories in response to a select signal S, a second select unit which may selectively output a data input from the first select unit and/or a scan input from an input terminal in response to a scan enable signal SE, and a flip-flop which may output data output from the second select unit to an output terminal in response to a clock signal CK.

### CROSS-REFERENCE TO RELATED APPLICATIONS

This U.S. nonprovisional patent application claims priority under 35 U.S.C. § 119 of Korean Patent Application 2003-74686 filed on Oct. 24, 2003, the entire contents of which are hereby incorporated by reference.

### BACKGROUND OF THE INVENTION

The present invention may relate to a scan test method, device, and system, and more particularly, to a scan test method, device, and system for reducing an overhead of a semiconductor chip.

Fault coverage may correspond to a ratio of the number of detected faults to the total number of generated faults (defects), for example, 95% of the fault coverage may indicate that 95% of faults in a semiconductor chip may be detected.

Test coverage of a semiconductor chip may enable the recognition of where a fault may have been generated in the semiconductor chip, and may take an appropriate action for the generated fault.

FIG. 1A illustrates an example of fault detection. A semiconductor chip 1 may have a plurality of input pins (for example, input 1 to input n) and a plurality of output pins (for example, output 1 to output n). Data and a test vector may be input to the plurality of input pins (input 1 to input n), and output from the plurality of output pins (output 1 to output n) through an internal circuit of the semiconductor chip. A vector corresponding to the fault may be input through the input pin, detect a fault, and verify the result through the output pin which may what part of the semiconductor chip may have generated the fault.

FIG. 1B is a view illustrating the example of a conventional semiconductor chip as illustrated in FIG. 1A, which may be, for example, a logical product gate (for example, an ‘AND’ gate). As shown in FIG. 1B, a logical product gate G may include two input pins (for example, input 1 and input 2), one output pin (for example, output 1) and three internal nodes (for example, node 1, node 2 and node 3). A fault may be detected using “single stuck at fault”, which may be used in a fault detection algorithm in which a fault may be generated at one node.

A fault of “stuck at 1” at node 1, may be verified by the result of an output pin (for example, output 1) when a value of ‘0’ and a value of ‘1’ may be input to an input pin (for example, input 1) and another input pin (for example, input 2). An output of ‘0’ through the output pin (for example, output 1) may indicate a fault of “stuck at 1” at a node (for example, node 1). An output of ‘1’ through the output pin (for example, output 1) may indicate a fault of “stuck at 1” at the node (node 1). The fault detection may be performed at other nodes in the same manner.

Each node may be controlled depending on the input pin and may facilitate detection of a fault at each node of the semiconductor chip. That is, a value of the node (node 1) may vary depending on a value of ‘1’ or ‘0’ input to the input pin (input 1) and may detect the fault at the node (node 1) of the logical product gate G. The output result of the output pin (output 1) may indicate to which the value of each node may be transmitted. That is, an output pin (output 1) of the logical product gate G which may have the value of ‘0’ or ‘1’ may indicate whether or not the fault may be generated at the node (node 1).

A sequential logic circuit for example, a flip-flop, controlling an internal node may be more difficult, due to a clock difference of one cycle that may be generated between a front terminal node and a rear terminal node. That is, it may be difficult to input an appropriate value to the input pin in view of the above cycle.

Accordingly, it may more difficult to detect a fault in semiconductor chips which may have many flip-flops. A full scan way may allow all flip-flops of the semiconductor chip to be replaced with the scan cells of FIG. 2A. The replaced scan cells may be connected in a chain type as shown in FIG. 2B.

FIG. 2A is a circuit diagram illustrating a conventional scan cell. As shown in FIG. 2A, the scan cell 2 may include a multiplexer 10 which may selectively output a data input DI and a scan input SI which may be in response to a scan enable signal SE; and a flip-flop 20 which may for output the output of the multiplexer 10 through a final output Q in response to the clock signal CK. The scan cell 2 may operate in a capture mode and may perform an operation of a general flip-flop according to the scan enable signal SE, and/or operate in a shift mode to input the scan data. In the capture mode the scan enable signal SE may have a value of ‘0’ and original input data input through a data input DI pin may be selected and input to a terminal D of the flip-flop 20. In the capture mode, the scan cell 2 may operate the same, or substantially the same, as the general flip-flop except for the addition of a delay operation which may use the multiplexer 10. In the shift mode the scan enable signal SE may have a value of ‘1’ and the scan input SI may be selected and input to the terminal D of the flip-flop 20. In the shift mode the scan cell 2 may input data for fault detection to a scan input SI terminal.

FIG. 2B is a view illustrating a chain-connection of the scan cell of FIG. 2A. In FIG. 2B, three scan cells (2_i; i=1, 2, 3) may be series-connected with one another. A desired value may be input to each of internal nodes (node a, node b and node c) of the chain-connected scan cells of FIG. 2B. The values of ‘1’, ‘1’ and ‘0’ may be input to the internal nodes (node a, node b and node c) by inputting (for example, sequentially) the values of ‘0’, ‘1’ and ‘1’ to the scan input SI terminal for a three-clock cycle. The flip-flop, which may be an internal sequential logic circuit, may detect a fault in a semiconductor chip in the same, or substantially the same, fault detection manner as that of the combination logic circuit.

Conventional semiconductor chips may include an embedded memory such as Read Only Memory (ROM) and Random Access Memory (RAM). In the above method of fault detection, in which the scan cell may be replaced with the flip-flop, a conventional scan cell of FIG. 2A may be connected to the boundary of the embedded memory and data may be shifted in the shift mode. However, the embedded memory may not perform fault detection because a conventional scan cell of FIG. 2A because data may be delayed by one cycle due to the flip-flop of the scan cell in the capture mode.

FIG. 3 is a block diagram illustrating a conventional semiconductor chip with logic circuits and an embedded memory. As shown in FIG. 3, input ports, which may be address and control signal input ports AC1 to ACn, data input ports DI1 to DIm and data output ports (DO1 to DOm), may be connected with embedded memory 30, and may be the same, or substantially the same, as a floating input and/or an output at the time of the fault detection. The input ports and the output ports of the embedded memory 30, through which the value may be input and output via a memory cell, may not be complete combinational logic circuits. Accordingly, it may be impossible that a fault may be detected at each of the input ports of the embedded memory 30 in a the same, or substantially the same, manner as in the combinational logic circuit.

In the conventional semiconductor chip 1, the embedded memory 30 may be tested using a Built In Self Test (BIST) without an Automatic Test Pattern Generation (ATPG). At the time of the ATPG, the embedded memory 30 may be black-boxed such that ports connected to the embedded memory 30 may be excluded. The fault may not be detected at all input ports and/or output ports of the embedded memory 30, which may cause the fault coverage to deteriorate in the semiconductor chip 1.

Scan cells may be connected to the boundary of the embedded memory 30 and may detect the fault from the embedded memory 30 of the semiconductor chip 1, thereby enhancing the fault coverage.

FIG. 4 is a block diagram illustrating the conventional semiconductor chip which may include logic circuits, embedded memory and scan cells. FIG. 4 illustrates only one of an address and control signal AC1, a data input DI1, and a data output D01, for description convenience. As shown in FIG. 3, there may be provided a plurality of address and control signals (AC1 to ACn), a plurality of data inputs (DI1 to DIn) and a plurality of data outputs (DO1 to DOn). Scan cells 40 and 50 may be provided for the address and control signals (AC1 to ACn) and the data inputs (DI1 to DIn), respectively.

Referring to FIG. 4, an upper scan cell 40 may include a multiplexer 11 which may selectively output the address and control signal AC1 and/or the scan input SI, in response to the scan enable signal SE; and a flip-flop 21 which may output the selected output of the multiplexer 11 to an output terminal Q, in response to the clock signal CK.

A lower scan cell 50 may include a multiplexer 12 which may selectively outputting the data input DI1 and/or the scan input SI, in response to the scan enable signal SE; and a flip-flop 22 which may output the selected output of the multiplexer 12 to an output terminal Q, in response to the clock signal CK. A tribuffer 60 may be provided at the output terminal Q of the scan cell 50 and may select a normal operation and/or a scan test operation in response to a test enable signal TE.

In a normal mode, a value of ‘0’ may be input as the test enable signal TE, and data may be input and output to and from a normal memory. In a test mode, a value of ‘1’ may be input as the test enable signal TE, and the scan cell may operate in the same, or substantially the same, manner as a conventional scan cell.

In a shift mode, the scan enable signal SE and the test enable signal TE may have the value of ‘1’, and the scan input SI may be selected in the multiplexer 12 and output to the data input terminal D of the flip-flop 22. The scan input SI may be output as a final output SO through the tribuffer 60, in response to the clock signal CK. In a capture mode the scan enable signal SE may have a value of ‘0’, and the data input DI1 may be selected in the multiplexer 12 and output to the data input terminal D of the flip-flop 22. The data input DI1 may be output as a final output SO through the tribuffer 60, in response to the clock signal CK.

The scan cells may be chain-connected such that, at the time of the ATPG, desired data may be input as the scan input and may be shifted to a desired node to perform the fault detection operation. The input node (AC1 or DI1) of the embedded memory 30 may be observed at the input pins (input 1 to input n) of the semiconductor chip. The chain-connection of the scan cell may allow the shift to control the output node DO1 of the memory using the output pins (output 1 to output n) of the semiconductor chip.

The scan cell may increase the control and the observability for a memory boundary signal to resultantly increase the controllability and the observability of the whole semiconductor chip, which may include the embedded memory, and may improve the fault coverage of the semiconductor chip.

Scan cells may be added to improve the fault coverage of the embedded memory and may result in an increase in the overhead of the entire semiconductor chip. The overhead may further increase as the embedded memories increase in number according to a high-density integration of a semiconductor chip.

Table 1 is a diagram for describing the increase in overhead according to the increasing number of the embedded memories.

TABLE 1
The number of the ports of the embedded memories

| | | | | | | | | | | #Port |
|---|---|---|---|---|---|---|---|---|---|---|
| CONFIG | #Unit | A | BWEN | DOUT | CSN | WEN | OEN | #Port/Unit | #Port | (DOUT) |
| 1024 * 32 | 4 | 10 | 32 | 32 | 1 | 1 | 1 | 77 | 308 | 128 |
| 128 * 22 | 4 | 7 | 22 | 22 | 1 | 1 | 1 | 54 | 216 | 88 |
| 128 * 24 | 4 | 7 | 24 | 24 | 1 | 1 | 1 | 58 | 232 | 96 |
| 128 * 32 | 2 | 7 | 32 | 32 | 1 | 1 | 1 | 74 | 148 | 64 |
| 128 * 8 | 1 | 7 | 8 | 8 | 1 | 1 | 1 | 26 | 26 | 8 |
| 32 * 64 | 2 | 5 | 64 | 64 | 1 | 1 | 1 | 136 | 272 | 128 |
| 32 * 8 | 2 | 5 | 8 | 8 | 1 | 1 | 1 | 24 | 48 | 16 |
| 512 * 32 | 16 | 9 | 32 | 32 | 1 | 1 | 1 | 76 | 1216 | 512 |
| 64 * 8 | 3 | 6 | 8 | 8 | 1 | 1 | 1 | 25 | 75 | 24 |
| Total | 38 | 63 | 230 | 230 | 9 | 9 | 9 | 550 | 2541 | 1064 |
| Max | 16 | 10 | 64 | 64 | 1 | 1 | 1 | 141 | * | * |

Referring to the Table 1, the semiconductor chip may include a total of 38 embedded memories including four embedded memories having 1024*32 constructions, four embedded memories which may have 128*22 constructions and the like. Each of the embedded memories may include the ports A, BWEN, CSN, WEN and OEN for inputting address and control signals; and the ports DOUT for outputting data.

For example, the input ports of the embedded memory (for example, CONFIG 1024*32), which may be disposed at a first row of the Table 1, may be described in the following:
#Unit: four embedded memories which may have the 1024*23 constructions,
A: 10 bits of address which may be required for accessing the embedded memory (for example, 1024*32),
BWEN: 32 bits of control signal which may be required for a bit write enable,
DOUT: 32 bits which may be required for data output,
CSN: one bit of control signal which may be required for a chip select enable,
WEN: one bit of control signal which may be required for a write enable,
OEN: one bit of control signal which may be required for an output enable,
#Port/Unit: 77 ports which may be required for a unit embedded memory (for example, 1024*32),
#Port: 308 ports which may be required for four embedded memories (for example, 1024*32), and
#Port (DOUT): 128 data output ports which may be required for four embedded memories (for example, 1024*32).

FIG. 5 is a block diagram illustrating the conventional semiconductor chip with the embedded memories and the scan cells. Four embedded memories 31, 32, 33 and 34 of FIG. 5 may have the 1024*32 constructions of the Table 1. Each of the embedded memories may include ports for inputting the address and control signals, and ports for inputting and outputting data, as described in Table 1.

FIG. 5 schematically illustrates a conventional semiconductor chip for drawing simplicity and description convenience. The embedded memories may include scan cells corresponding to the number of the ports. For example, the embedded memory 31 may include forty-five scan cells 41 corresponding to the number of the address and control signal ports, and thirty-two scan cells 51 corresponding to the number of the data input and output ports. Seventy-seven scan cells may be present per one embedded memory, and three-hundred eight scan cells may be present for four embedded memories. The semiconductor chip may have four embedded memories of FIG. 5, and the total area of the scan cells may be obtained in the following: Area (wrapper)=Area (scan cell)*308.

The scan cell may be constructed according to the Table 1, and 2541 numbers of scan cells may be present since 38 embedded memories include 2541 numbers of ports. That is, the total area of the scan cell may be obtained through the following equation: Area (wrapper)=Area (scan cell)*2541.

However, the scan cell which may used to test and the logic circuit which may be used for the normal operation may have very large area ratio. Specifically, many embedded memories may be additionally installed and the ratio of the area (wrapper) to the area (normal function) may be 10% or greater, thereby causing more larger overhead in which the total area of the semiconductor chip may be increased due to the scan cell.

### SUMMARY OF THE INVENTION

Exemplary embodiments of the present invention provide a scan test method, device, and system which may reduce the overhead of a semiconductor chip by sharing scan cells connected to input/output ports of an embedded memory, and may detect faults in a plurality of embedded memories.

An exemplary embodiment of the present invention provides a scan test device which may include at least one first select unit which may selectively output, in response to a select signal, at least one data input port which may be connected to at least one of the plurality of embedded memories, for detecting a fault in the selected embedded memory, a second select unit which may selectively output, in response to a scan enable signal, data from the first select unit and/or scan data from an input terminal, and a flip-flop which may output data from the second select unit to an output terminal, in response to a clock signal.

Another exemplary embodiment of the present invention provides a scan test device which may detect faults in a plurality of embedded memories which may have the same construction and/or different constructions. The scan test device may include at least one first select unit which may selectively output, in response to a select signal, at least one data input port which may be connected to at least one of the plurality of embedded memories, and may detect a fault in the selected embedded memory, a second select unit which may selectively output, in response to a scan enable signal, data from the first select unit and/or scan data from an input terminal; and a flip-flop which may output data from the second select unit to an output terminal in response to a clock signal. The plurality of embedded memories may include a plurality of embedded memories which may have the same construction and at least one embedded memory which may have a different construction.

Another exemplary embodiment provides a scan test device which may detect faults in a plurality of embedded memories which may have the same construction and/or different constructions. The scan test device may include at least one first select unit which may selectively output, in response to a select signal, at least one data input port connected to at least one of the plurality of embedded memories, usable for detecting a fault in the selected embedded memory, and an output unit which may selectively output data from the first select unit and/or scan data from an input terminal.

Another exemplary embodiment of the present invention provides a method for detecting faults in a plurality of embedded memories, the method may comprise selecting data input from at least one of a plurality of embedded memories, in response to a select signal, to output for detecting a fault in the selected embedded memory, and selectively outputting at least one of data from the first select unit and scan data from an input terminal. The plurality of embedded memories may includes a plurality of embedded memories with the same construction and at least one embedded memory which may have a different construction.

Another exemplary embodiment of the present invention provides a scan test device, and method for the same, which may select data input from at least one of a plurality of embedded memories in response to a select signal, and may selectively output a signal usable for detecting a fault in the selected embedded memory.

Another exemplary embodiment of the present invention provides a scan test system which may comprise at least one embedded memory, and at least one scan test device. The at least one scan test device may select data input from at least one of a plurality of embedded memories in response to a select signal and may selectively output a signal usable for detecting a fault in the selected embedded memory.

In exemplary embodiments of the present invention the scan test device may include a third select unit for performing a normal operation or a test operation in response to a test enable signal. Exemplary embodiments of the present invention may include embedded memories having the same construction.

In exemplary embodiments of the present invention the at least one first select unit may receive data from each of data input ports, which may be connected to the at least one of the plurality of embedded memories, and may perform the same function.

In exemplary embodiments of the present invention the second select unit may output data from the first select unit in a capture mode where the scan enable signal may be disabled, and outputs scan data from the input terminal in a shift mode where the scan enable signal may be enabled.

In exemplary embodiments of the present invention the scan test device may include a third select unit for performing a normal operation and/or a test operation which may be in response to a test enable signal.

In exemplary embodiments of the present invention the embedded memories may have different numbers of data input ports which may perform the same function.

In an exemplary embodiment of the present invention the first select unit may receive data from each of data input ports which may perform the same function.

In exemplary embodiments of the present invention the first select unit may be provided in the same number as that of one or more embedded memories which may each have maximal number of the data input ports which may perform the same function.

In exemplary embodiments of the present invention the second select unit may output data from the first select unit in a capture mode where the scan enable signal SE may be disabled, and may output scan data from the input terminal in a shift mode where the scan enable signal SE may be enabled.

In exemplary embodiments of the present invention the third select unit may perform a normal operation in a normal mode where the test enable signal TE may be disabled, and may perform a test operation in a test mode where the test enable signal TE may be enabled.

### BRIEF DESCRIPTION OF THE DRAWINGS

The above and other features and advantages exemplary embodiments of the present invention will may become more apparent by describing in detail preferred exemplary embodiments thereof with reference to the attached drawings in which:

FIG. 1A illustrates an example of conventional fault detection

FIG. 1B is an example of a circuit diagram of FIG. 1A;

FIG. 2A is an example of a circuit diagram illustrating a conventional scan cell;

FIG. 2B is a view illustrating an example of a chain-connection of the conventional scan cell of FIG. 2A;

FIG. 3 is a block diagram illustrating an example of a conventional semiconductor chip with logic circuits and an embedded memory;

FIG. 4 is a block diagram illustrating an example of a conventional semiconductor chip with an embedded memory and a scan cell connected to an input port of the embedded memory;

FIG. 5 is a block diagram illustrating an example of a conventional semiconductor chip with a plurality of embedded memories;

FIG. 6 is a circuit diagram illustrating a scan test device according to exemplary embodiments of the present invention;

FIG. 7 is a block diagram illustrating an example of a semiconductor chip which may have embedded memories which may have the same, or substantially the same, construction and a scan test device of FIG. 6; and

FIG. 8 is a block diagram illustrating an example of a semiconductor chip which may have embedded memories which may have different constructions and a scan test device of FIG. 6.

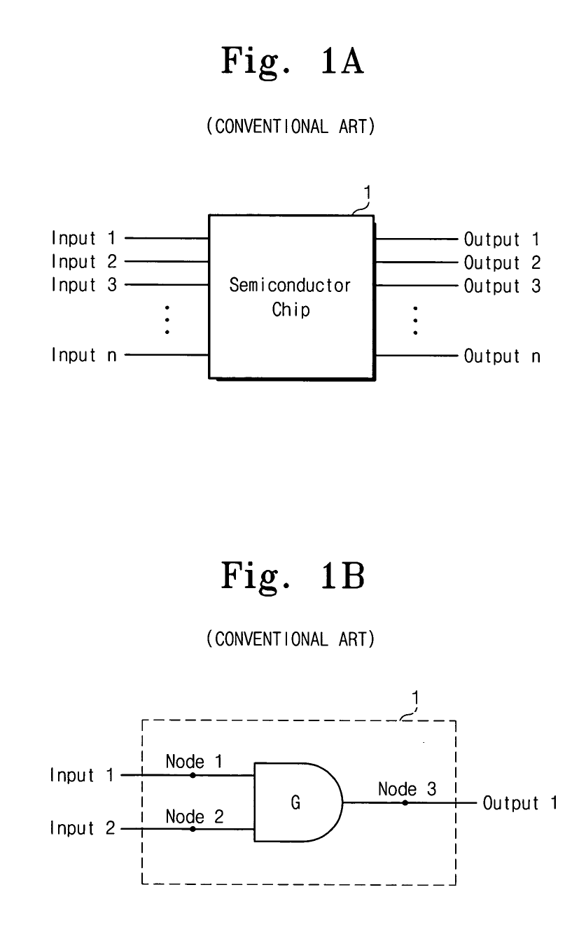

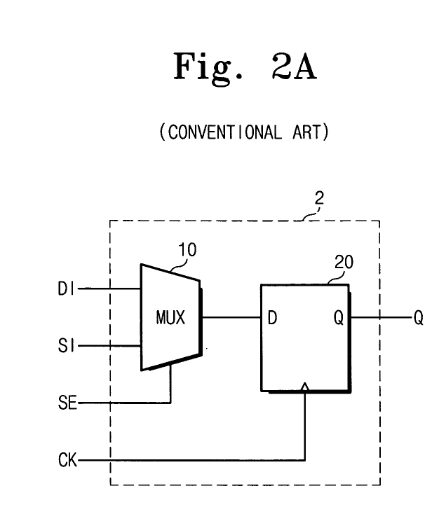

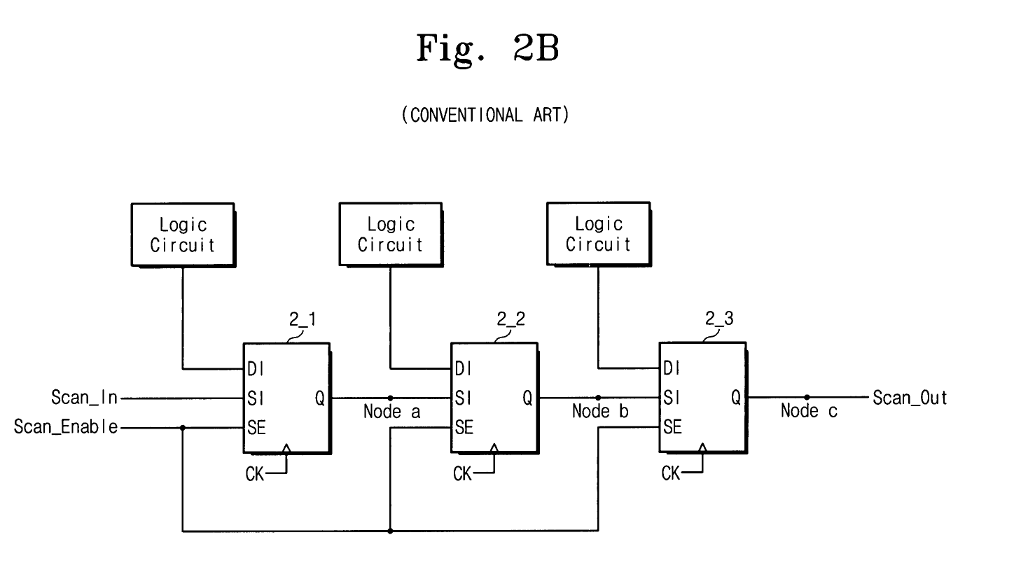

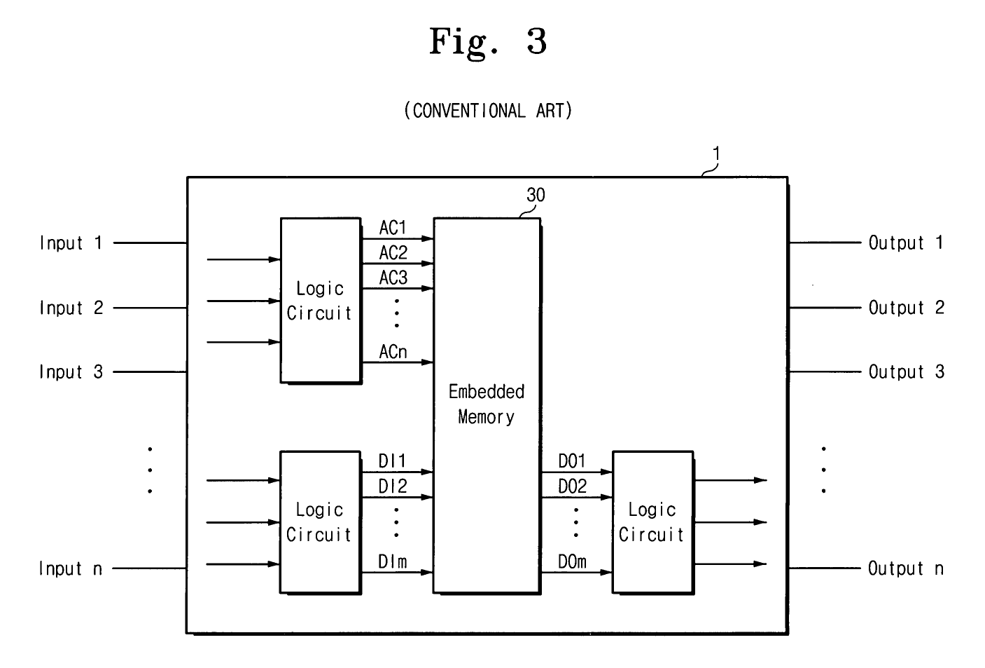

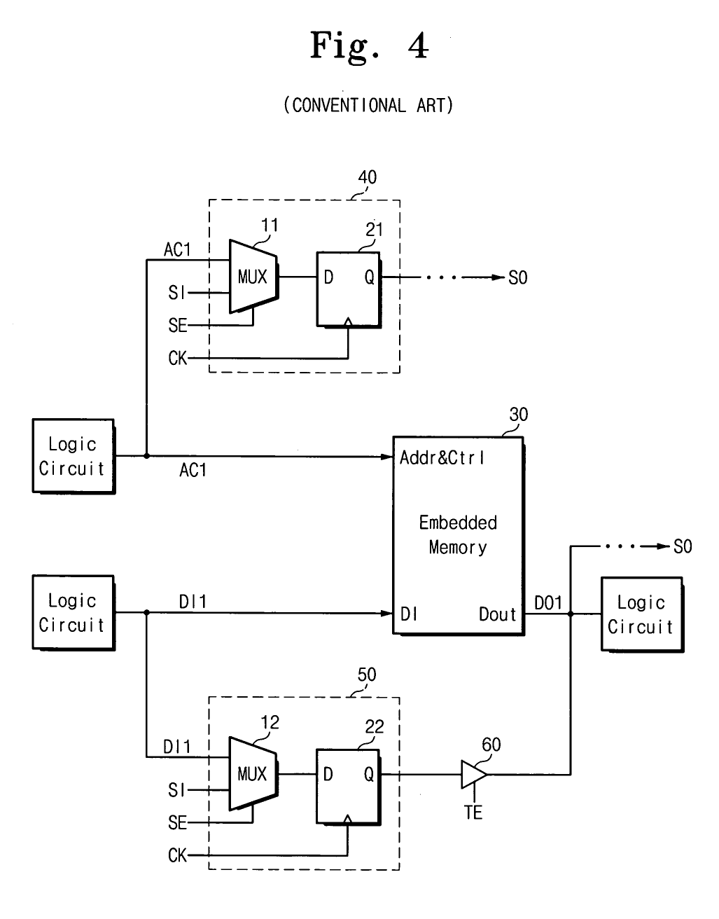

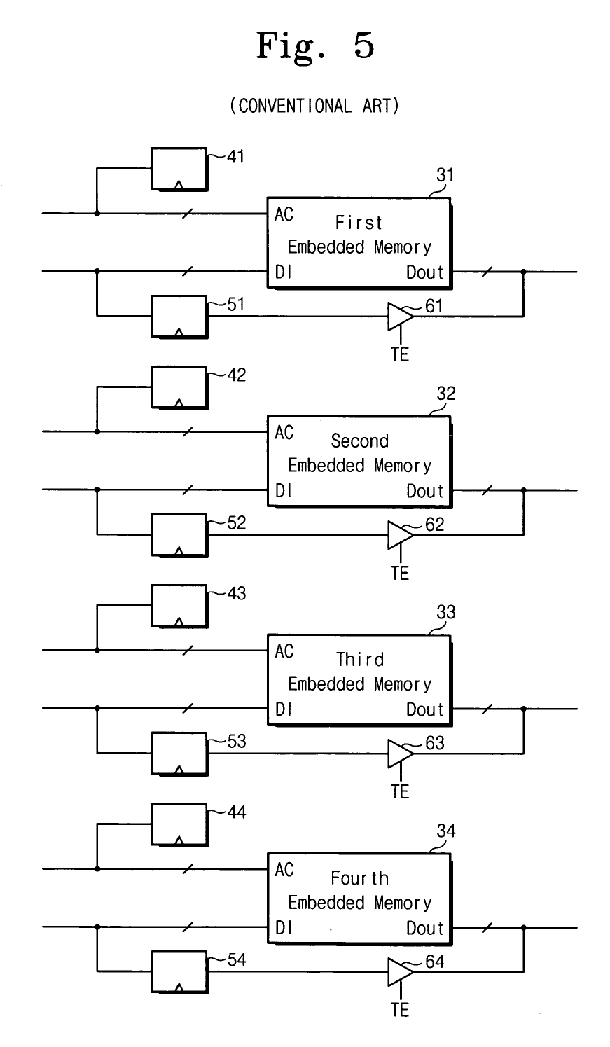

### DETAILED DESCRIPTION OF THE INVENTION

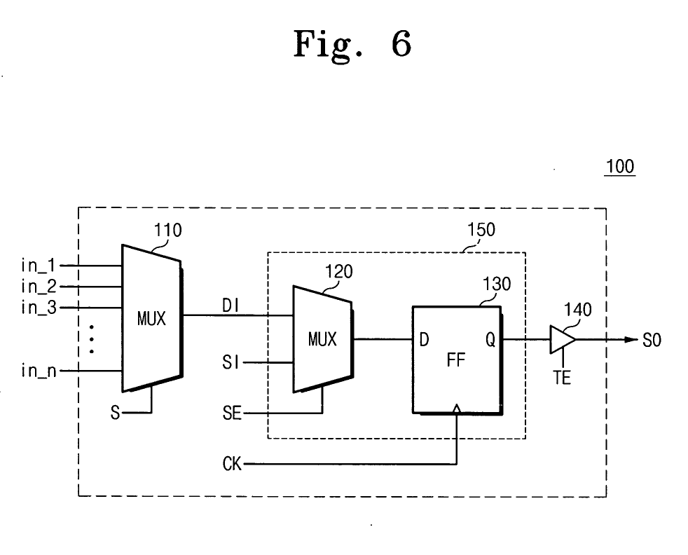

FIG. 6 is a circuit diagram illustrating a scan test device according to exemplary embodiments of the present invention. The scan test device 100 may detect faults in embedded memories which may have the same, or substantially the same, construction and/or embedded memories which may have different constructions.

The scan test device 100 may include a first select unit 110 which may selectively output data inputs (in_k; k=1 to n), which may detect faults in the embedded memories, in response to a select signal S; a second select unit 120 which may selectively output a data input from the first select unit 110 and/or a scan input from an input terminal, in response to a scan enable signal SE; and a flip-flop 130 which may output data from the second select unit 120 to an output terminal in response to a clock signal CK. The scan test device 100 may also include a third select unit which may perform a normal operation and/or a test operation in response to a test enable signal TE.

In an exemplary embodiment of the present invention, the first select unit 110 (for example, a multiplexer) may receive data from input ports of the embedded memories, and may selectively output the received data in response to a select signal S. The embedded memories may have the same and/or different constructions. The multiplexer 110 may receive data inputs (in_k; k=1 to n) from the input ports, which may perform the same, or substantially the same, function as the embedded memories.

The input ports may perform the same, or substantially the same, function and may refer to address input ports, control signal input ports and/or data input ports. For example, ten Address (A)-input ports of the embedded memories may have, for example, 1024*32 constructions in Table 1 which may perform the same, or substantially the same, address input functions. The ten Address (A)-input ports of the embedded memories which may have the, for example, 1024*32 constructions, and/or seven Address (A)-input ports of the embedded memories, which may have, for example, 128*22 constructions, may perform the same, or substantially the same function, respectively.

The first select unit 110 may receive data from the embedded memories which may have the same, or substantially the same, construction (for example, four embedded memories may have 1024*32 constructions), and may receive data from the embedded memories which may have different constructions (for example, the embedded memories may have 1024*32 constructions and/or the embedded memories may have the 128*22 constructions). The first select unit 110 may also receive data (for example, concurrently) from embedded memories which may have the same, substantially the same, or different constructions.

A selected data input may be transmitted to the second select unit 120 in response to a select signal S from the data inputs (in_k; k=1 to n) input to the first select unit 110.

The second select unit 120 and/or the flip-flop 130 may refer to a scan cell 150. The scan cell 150 may be comprised of the multiplexer 120, which may selectively output a data input DI and/or a scan input SI in response to a scan enable signal SE; and a flip-flop 130 which may output an output of the multiplexer 120 as a final output Q, in response to a clock signal CK.

The scan cell 150 may operate in a capture mode and may perform the same, or substantially the same, operation as a conventional flip-flop according to the scan enable signal SE. The scan cell may operate in a shift mode and use shift to input scan data. In the capture mode, the scan enable signal SE may have a value of ‘0’, may select and may input original data, input through a data input DI pin, to a data input terminal of the flip-flop 130. The scan cell 150 may operate in the same, or substantially the same, manner as the general flip-flop and may perform an additional delay operation using the multiplexer 120. In the shift mode a scan enable signal SE may have a value of ‘1’, may select and may output a scan input I to a data input terminal D of the flip-flop 130, thereby inputting data to a scan input SI terminal which may be for a fault detection.

The third select unit 140 may refer to a tribuffer, which may be disposed at an output terminal of the scan cell and may select a normal operation and/or a scan test operation in response to a test enable signal TE.

In a normal mode, a value of ‘0’ may be input as the test enable signal TE, and data may be input and/or output to and from a normal memory. In a test mode, a value of ‘1’ may be input as the test enable signal TE, and may operate in the same, or substantially the same, manner as the conventional scan cell.

In a shift mode the scan enable signal SE may have the value of ‘1’ and the test enable signal TE may have the value of ‘1’. The scan input SI may be selected in the multiplexer 120 and may be output to the data input terminal D of the flip-flop 130 and the scan input SI may be output as a final output SO through the tribuffer 140, in response to a clock signal CK. In a capture mode the scan enable signal SE may have the value of ‘0’, the data input DI1 may be selected in the multiplexer 120 and output to the data input terminal D of the flip-flop 130. The data input DI1 may be output as a final output SO through the tribuffer 140, in response to the clock signal CK.

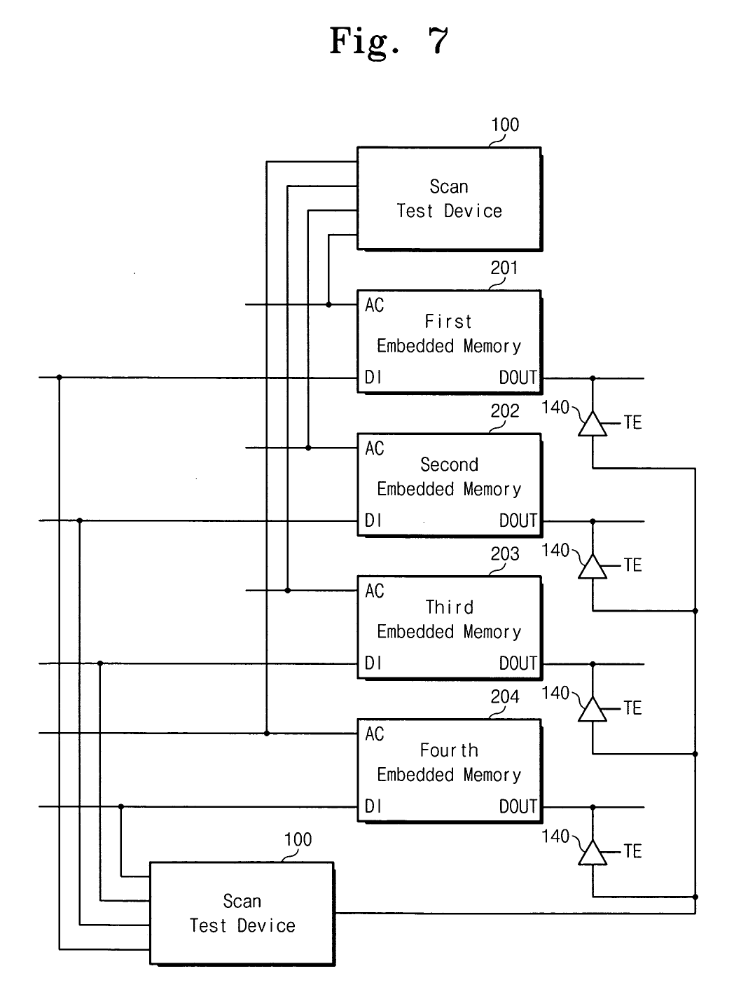

FIG. 7 is a block diagram illustrating a semiconductor chip with embedded memories which may have the same, or substantially the same, construction and the scan test device of FIG. 6.

In FIG. 7, the embedded memories 201 to 204 may have the same, or substantially the same, construction. For example, four embedded memories, which may have, for example the 1024*32 constructions, may be illustrated. The scan test device 100 may include a first select unit 110, a second select unit 120 and a flip-flop 130.

The scan test device 100 may receive data through the input ports and may perform the same, or substantially the same, function. For example, each of the embedded memories, 201 to 204 which may have the same, or substantially the same, 1024*32 constructions in Table 1, may have input ports A, BWEN, CSN, WEN and OEN which may be for inputting address and/or control signals, and input ports DI for inputting data. The input ports may be illustrated for description convenience, and the scan test device 100 may actually be connected to every input port.

In a convention art method, the embedded memories may have, for example, the 1024*32 constructions, which may include forty-five input ports which may input the address and/or the control signals, and thirty-two input ports which may input data. Seventy-seven scan cells may be present per embedded memory. In the semiconductor chip, which may have the four embedded memories, three hundred eight scan cells may be present.

The present invention may have seventy-seven scan test devices 100 in the semiconductor chip, which may include the four embedded memories. That is, seventy-seven scan cells may be provided since the multiplexer 110 may be used to share the scan cell. The number of the scan cells may be reduced to one fourth, which may reduce the overhead. As the embedded memories may increase, the overhead may be reduced.

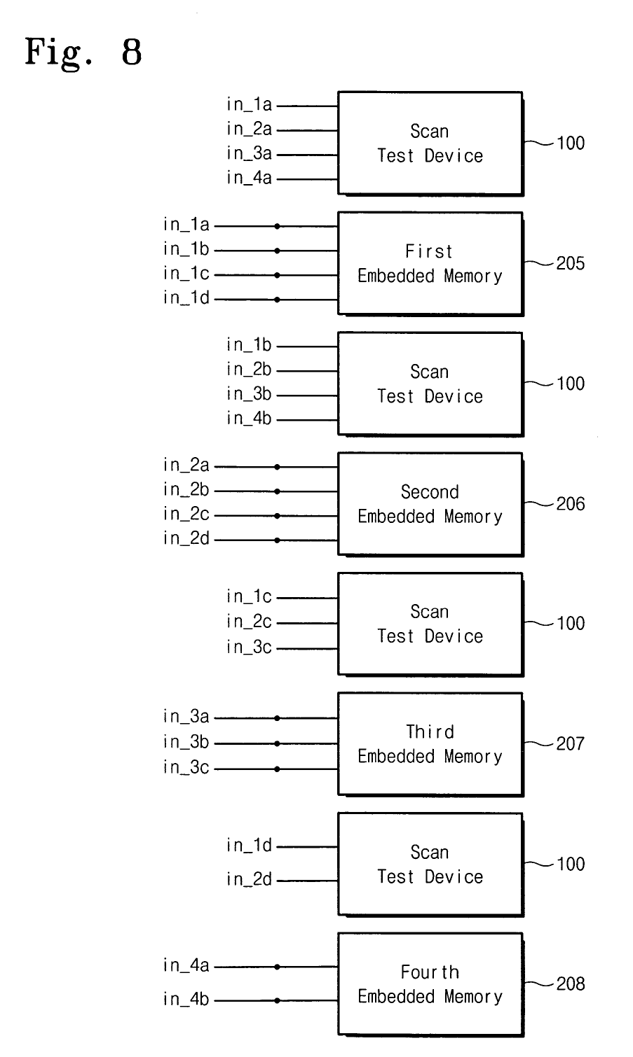

FIG. 8 is a block diagram illustrating the semiconductor chip which may have embedded memories which may have the different constructions and the scan test device of FIG. 6.

FIG. 8 illustrates the embedded memories 205 and 206, which may have the same, or substantially the same, construction, and the embedded memories 207 and 208 which may have the different constructions. For example, the first embedded memory 205 and/or the second embedded memory 206 may have the 1024*32 constructions, the third embedded memory 207 may have the 128*22 construction, and the fourth embedded memory 208 may have the 128*24 construction. The embedded memories 205 to 208 may have the input ports which may perform the same, or substantially the same, function.

To determine the fault coverage of the input ports, the conventional scan test device may require thirteen scan cells, however, four scan test devices may be provided in an exemplary embodiment of the present invention, as shown in FIG. 8.

The semiconductor chip may include embedded memories which may have different constructions, and/or embedded memories which may have a different number of input ports, which may perform the same, or substantially the same, function. The first and/or second embedded memories may have four input ports, and the third embedded memory and/or fourth embedded memory may have two input ports, respectively. A number of multiplexers 110 according to the greatest number of input ports may be present to share any or all of the embedded memories. That is, four scan test devices may be present in the exemplary embodiment of the present invention, as illustrated in FIG. 8.

The largest values at each of columns may be arranged at the last row (Max) of the Table 1. That is, the ‘A’ may have the largest value of, for example ‘10’ in the embedded memory (for example, 1024*24), and the ‘BWEN’ may have the largest value of, for example, ‘64’ in the embedded memory (for example, 32*64).

The largest value may allow the scan test device 100 to share any or all of the embedded memories of the Table 1. That is, ten multiplexers may allow ten scan cells to share the input ports A of all embedded memories. Sixty-four multiplexers may allow sixty-four scan cells to share the input ports (BWEN) of any or all embedded memories. Sixty-four multiplexers may allow sixty-four scan cells to share the input ports DOUT. One hundred forty-one scan cells may perform a scan operation for each of the ports.

In a conventional method, 2541 scan cells may be present since thirty-eight embedded memories may have 2541 input ports in total. That is, the total area of the scan cells may be obtained through the following equation: Area (wrapper)=Area (scan cell)*2541. However, according to exemplary embodiments of the present invention, the total area of the scan cells may be obtained through the following equation: Area (wrapper)=Area (scan cell)*141. Accordingly, exemplary embodiments of the present invention may obtain a result of, for example, 141/2541*100=5.5%.

Although exemplary embodiments of the present invention have been described as using embedded memory structures as described in Table 1 (for example, 1024*32), it will be apparent than any memory structure may be used as desired by one of ordinary skill in the art.

Although exemplary embodiments of the present invention have been described as using values of ‘1’ and/or ‘0’, it will be apparent that any similar, or substantially similar, logic value may be used as desired by one of ordinary skill in the art.

As described above, the inventive scan test device may have an effect in that the multiplexer may be used to share the scan cells, thereby reducing the overhead drawback, which may be caused by the increase in the number of the scan cells according to the increase in the number of the embedded memories.

It will be apparent to those skilled in the art that various modifications and variations may be made in the present invention. Thus, it may be intended that the present invention may cover the modifications and variations of this invention provided they come within the scope of the appended claims and their equivalents.

1. A scan test device for detecting faults in a plurality of embedded memories, the device comprising:
at least one first select unit adapted to selectively output, in response to a select signal, at least one data input port connected to at least one of the plurality of embedded memories, for detecting a fault in the selected embedded memory;
a second select unit adapted to selectively output, in response to a scan enable signal, at least one of data from the first select unit and scan data from an input terminal; and
a flip-flop adapted to output data from the second select unit to an output terminal, in response to a clock signal.

2. The device of claim 1, further comprising a third select unit for performing a normal operation or a test operation in response to a test enable signal.

3. The device of claim 1, wherein the plurality of embedded memories have the same construction.

4. The device of claim 3, wherein the at least one first select unit receives data from at least one data input port, connected to the at least one of the plurality of embedded memories, which performs the same function.

5. The device of claim 3, wherein the second select unit outputs data from the first select unit in a capture mode where the scan enable signal is disabled and outputs scan data from the input terminal in a shift mode where the scan enable signal is enabled.

6. The device of claim 3, wherein the third select unit performs a normal operation in a normal mode where the test enable signal is disabled, and performs a test operation in a test mode where the test enable signal is enabled.

7. The device of claim 1, wherein the plurality of embedded memories have at least two different constructions.

8. The device of claim 7, further comprising a third select unit for performing a normal operation or a test operation in response to a test enable signal.

9. The device of claim 7, wherein the plurality of embedded memories have a plurality of different data input ports adapted to perform the same function.

10. The device of claim 9, wherein the at least one first select unit receives data from each of the data input ports adapted to perform the same function.

11. The device of claim 1, wherein the number of first select units is equal to the number of embedded memories, and each first select unit has a plurality of data input ports adapted to perform the same function.

12. The device of claim 9, wherein the second select unit outputs data from the first select unit in a capture mode where the scan enable signal is disabled, and outputs scan data from the input terminal in a shift mode where the scan enable signal is enabled.

13. The device of claim 9, wherein the third select unit performs a normal operation in a normal mode where the test enable signal is disabled, and performs a test operation in a test mode where the test enable signal is enabled.

14. A scan test device for detecting faults in a plurality of embedded memories, the device comprising:
at least one first select unit adapted to selectively output, in response to a select signal, at least one data input port connected to at least one of the plurality of embedded memories, for detecting a fault in the selected embedded memory;
a second select unit adapted to selectively output, in response to a scan enable signal, at least one of data from the first select unit and scan data from an input terminal; and
a flip-flop for outputting data from the second select unit to an output terminal in response to a clock signal; wherein
the plurality of embedded memories includes a plurality of embedded memories having the same construction and at least one embedded memory having a different construction.

15. The device of claim 14, further comprising a third select unit for performing a normal operation or a test operation in response to a test enable signal.

16. The device of claim 14, wherein the plurality of embedded memories having the same construction have the same number of data input ports adapted to perform the same function, and the at least one embedded memory having the a different construction a different number of data input ports adapted to perform the same function.

17. The device of claim 16, wherein the first select unit receives data from each of the data input ports adapted to perform the same function.

18. The device of claim 17, wherein the number of first select units equal to is equal to the number of embedded memories, and each first select unit has a plurality of data input ports adapted to perform the same function.

19. The device of claim 16, wherein the second select unit outputs data from the first select unit in a capture mode where the scan enable signal is disabled and outputs scan data from the input terminal in a shift mode where the scan enable signal is disabled.

20. The device of claim 16, wherein the third select unit performs a normal operation in a normal mode where the test enable signal is disabled, and performs a test operation in a test mode where the test enable signal is enabled.

21. A scan test device for detecting faults in a plurality of embedded memories having the same construction and embedded memories having different constructions, the device comprising:
at least one first select unit adapted to selectively output, in response to a select signal, at least one data input port connected to at least one of the plurality of embedded memories, for detecting a fault in the selected embedded memory; and
an output unit adapted to selectively output at least one of data from the first select unit and scan data from an input terminal.

22. A method for detecting faults in a plurality of embedded memories, the method comprising:
selecting data input from at least one of a plurality of embedded memories, in response to a select signal, to output for detecting a fault in the selected embedded memory; and
selectively outputting at least one of data from the first select unit and scan data from an input terminal; wherein
the plurality of embedded memories includes a plurality of embedded memories with the same construction and at least one embedded memory having a different construction.

23. A scan test device adapted to select data input from at least one of a plurality of
embedded memories in response to a select signal, and selectively output a signal usable for detecting a fault in the selected embedded memory.

24. A scan test method comprising:
selecting data input from at least one of a plurality of embedded memories in
response to a select signal and selectively outputting a signal usable for detecting a fault in the selected embedded memory.

25. A scan test system comprising:
at least one embedded memory; and
at least one scan test device; wherein
the at least one scan test device is adapted to select data input from at least one of a plurality of embedded memories in response to a select signal and selectively output a signal usable for detecting a fault in the selected embedded memory.

26. A scan test system including the scan test device of claim 1.

27. A scan test system including the scan test device of claim 14.

28. A scan test system including the scan test device of claim 21.

29. A scan test system including the scan test device of claim 23.

30. A scan test device for implementing the method of claim 22.

31. A scan test device for implementing the scan test method of claim 24.

32. A scan test system including the scan test device of claim 30.

33. A scan test system including the scan test device of claim 31.
